(19) United States
(12) Patent Application Publication
(10) Pub. No.: US 2025/0176430 A1
(43) Pub. Date: May 29, 2025

(54) METHOD FOR PRODUCING A DONOR SUBSTRATE FOR TRANSFERRING A PIEZOELECTRIC LAYER, AND METHOD FOR TRANSFERRING A PIEZOELECTRIC LAYER TO A CARRIER SUBSTRATE

(71) Applicant: Soitec, BERNIN (FR)

(72) Inventors: Marcel Broekaart, BERNIN (FR); Cédric Charles-Alfred, BERNIN (FR); Luciana Capello, BERNIN (FR); Morgane Logiou, BERNIN (FR); Thierry Barge, BERNIN (FR)

(21) Appl. No.: 18/728,998

(22) PCT Filed: Jan. 11, 2023
(86) PCT No.: PCT/EP2023/050571

§ 371 Date: Jul. 15, 2024

(30) Foreign Application Priority Data
Jan. 17, 2022 (FR) FR2200380

(51) Int. Cl. H10N 30/073; H10N 30/086

(52) U.S. Cl. CPC H10N 30/073; H10N 30/086

(57) ABSTRACT

A method of manufacturing a donor substrate for the transfer of a piezoelectric layer onto a support substrate comprises providing a handling substrate and providing a piezoelectric substrate. A polymer layer is deposited on the handling substrate or the piezoelectric substrate. An intermediate layer is formed on a free surface of the piezoelectric substrate, and the piezoelectric substrate is assembled on the handling substrate such that the intermediate layer formed on the piezoelectric substrate is between the polymer layer and the piezoelectric substrate to form the donor substrate. A donor substrate may be manufactured by such a method, and such a donor substrate may be used for transferring a piezoelectric layer to another substrate.

### CROSS REFERENCE TO RELATED APPLICATIONS

This application is a national phase entry under 35 U.S.C. § 371 of International Patent Application PCT/EP2023/050571, filed Jan. 11, 2023, designating the United States of America and published as International Patent Publication WO 2023/135181 A1 on Jul. 20, 2023, which claims the benefit under Article 8 of the Patent Cooperation Treaty to French Patent Application Serial No. FR2200380, filed Jan. 17, 2022.

### TECHNICAL FIELD

The present disclosure relates to a process for the manufacture of a donor substrate for the transfer of a piezoelectric layer, to a donor substrate and to a process for transfer of such a piezoelectric layer onto a support substrate.

### BACKGROUND

A piezoelectric-on-insulator (POI) substrate comprises a thin layer of piezoelectric material on a substrate. In order to manufacture such a POI substrate, the process used comprises the transfer of the thin piezoelectric layer onto a support substrate starting from a thicker substrate of piezoelectric material.

For this, first a donor substrate is used in which a bulk substrate of piezoelectric material is assembled with a handling substrate by bonding using a polymer layer. Subsequently, the donor substrate is subjected to a stage of thinning the bulk piezoelectric substrate to form a thinner piezoelectric layer, before being assembled with the support substrate. Finally, the transfer of the piezoelectric layer onto the support substrate is carried out mechanically or thermally at the level of a fracturing zone created beforehand in the thinned piezoelectric layer. The donor substrate is introduced into the process in order to limit the negative impact of the difference in the thermal expansion coefficients between the piezoelectric material and the support substrate of the POI. This is because, in order to reinforce the bonding interface between the different substrates and the transfer of the thin layer, heat treatments are carried out. An example of this type are process is described in WO 2019/186032 A1.

As the donor substrate has to undergo several stages of heat and/or mechanical treatments, a debonding at the bonding interface between the piezoelectric substrate and the polymer layer can take place.

### BRIEF SUMMARY

One aim of the present disclosure is to overcome the abovementioned disadvantages and, in particular, to design a donor substrate for the transfer of a piezoelectric layer of a piezoelectric material substrate onto a support substrate, which exhibits a better mechanical strength.

The object of the present disclosure is achieved by a process for the manufacture of a donor substrate for the transfer of a piezoelectric layer onto a support substrate, comprising the stages of providing a handling substrate, in particular, a silicon-based substrate, providing a piezoelectric substrate, forming an intermediate layer on a free surface of the piezoelectric substrate, depositing a polymer layer on the intermediate layer of the piezoelectric substrate, and assembling the piezoelectric substrate on the handling substrate in order to form the donor substrate.

The formation of an intermediate layer between the piezoelectric substrate and the polymer layer makes it possible to obtain a more stable bond between the piezoelectric material and the polymer layer, by choosing an intermediate layer that exhibits good adhesion to the piezoelectric substrate and also to the polymer layer. Thus, the process according to the present disclosure makes it possible to obtain a donor substrate having an improved mechanical stability between the piezoelectric substrate and the polymer layer of the handling substrate, with respect to the state of the art.

The object of the present disclosure is also achieved by a process for the manufacture of a donor substrate for the transfer of a piezoelectric layer onto a support substrate, comprising the stages of providing a handling substrate, in particular, a silicon-based substrate, depositing a polymer layer on a free face of the handling substrate, providing a piezoelectric substrate, forming an intermediate layer on a free surface of the piezoelectric substrate, assembling the piezoelectric substrate on the handling substrate in such a way that the intermediate layer formed on the piezoelectric substrate is sandwiched between the polymer layer of the handling substrate and the piezoelectric substrate in order to form the donor substrate.

The formation of an intermediate layer between the piezoelectric substrate and the polymer layer of the handling substrate makes it possible to obtain a more stable bond between the piezoelectric material and the polymer layer, by choosing an intermediate layer that exhibits good adhesion to the piezoelectric substrate and also to the polymer layer. Thus, the process according to the present disclosure makes it possible to obtain a donor substrate having an improved mechanical stability between the piezoelectric substrate and the polymer layer of the handling substrate, with respect to the state of the art.

According to one embodiment, the formation of the intermediate layer can comprise the formation of a single layer or of several sublayers.

According to one embodiment, the formation of the intermediate layer can comprise at least the formation of a dielectric layer, in particular, a layer based on silicon oxide or on silicon nitride or a combination of silicon nitride and oxide SiOₓN_{y}. The use of a dielectric layer formed on a piezoelectric material makes it possible to assemble the piezoelectric substrate with another substrate to form a donor substrate via this dielectric layer. By virtue of the presence of the dielectric layer producing the connection between the piezoelectric substrate and the handling substrate, the donor substrate obtained has an improved mechanical stability for the different process stages to which the donor substrate will subsequently be subjected.

According to one embodiment, a stage of surface treatment of the intermediate layer can be carried out, in particular, a plasma treatment, more particularly still an oxygen O₂ plasma treatment. A plasma treatment is a treatment by the dry route, which makes possible the functionalization and/or the activation of the surface. The plasma surface treatment consists of a very strong oxidation of the surface of a material. The oxidation of the surface molecules makes it possible to increase the surface tension of a support. The plasma treatment makes possible the creation of free radicals at the surface, which promote the successive adhesion of a thin layer in contact with these free radicals. Thus, the plasma surface treatment makes it possible to improve the chemical characteristics of the material for better adhesion to a coating layer. Thus, the plasma treatment stage of the process according to the present disclosure makes it possible to improve the adhesion between the dielectric layer formed on the piezoelectric substrate and the polymer layer of the donor substrate, and results in an improved mechanical stability of the donor substrate with respect to the state of the art.

According to one embodiment, a stage of thinning the piezoelectric substrate of the donor substrate can be carried out, so as to obtain either a thinned piezoelectric substrate with a thickness t, which is less than the thickness t₁ of the piezoelectric substrate, or a piezoelectric layer with a thickness t₂, which is less than the thickness t₁ of the piezoelectric substrate. The thinning stage can be carried out by a grinding process or else by a process of chemical etching of the piezoelectric substrate. Thus, starting from a thick piezoelectric substrate, a thinner piezoelectric substrate or a piezoelectric layer of a thinner desired thickness is obtained and the donor substrate thus manufactured by the process according to the present disclosure can be used as donor substrate in a subsequent layer transfer process for transferring a fine layer of the piezoelectric material onto a support substrate in order to thus form a piezoelectric-on-insulator (POI) substrate. The use of a finer piezoelectric substrate makes it possible to reduce the subsequent problems due to non-symmetry of the thermal expansion coefficients and thus to minimize the deformation of the assembly during the application of subsequent process stages.

According to one embodiment, the assembling stage of the process for the manufacture of a donor substrate can comprise a stage of treatment of the polymer layer in order to obtain a crosslinked polymer layer in order to bond the handling substrate to the piezoelectric substrate. The formation of a crosslinked polymer layer by a stage of treatment of the polymer layer is simple to put in place and makes possible an adhesion that satisfies the conditions of the process.

The object of the present disclosure is also achieved by a donor substrate for the transfer of a piezoelectric layer, comprising a handling substrate, in particular, a silicon-based substrate, a piezoelectric substrate, a polymer layer sandwiched between the handling substrate and the piezoelectric substrate, and wherein the donor substrate additionally comprises an intermediate layer sandwiched between the piezoelectric substrate and the polymer layer. By virtue of the presence of the intermediate layer sandwiched between the piezoelectric substrate and the polymer layer, better linking is produced between the piezoelectric substrate and the polymer layer. This linking results in a donor substrate having an improved mechanical stability and makes it possible to use this donor substrate in processes a posteriori without encountering problems of debonding at the polymer-piezoelectric interface.

According to one embodiment, the intermediate layer can comprise a single layer or several sublayers.

According to one embodiment, the intermediate layer can comprise at least one dielectric layer, in particular, a layer based on silicon oxide and/or on silicon nitride or a combination of silicon nitride and oxide SiOₓN_{y}. The use of a dielectric layer formed on a piezoelectric material makes it possible subsequently to use the piezoelectric substrate for assembling with another substrate to form a donor substrate via this dielectric layer in a way that is sturdy and stable for the different process stages to which the donor substrate will subsequently be subjected.

According to one embodiment, the dielectric layer of the intermediate layer can be in direct contact with the polymer layer of the donor substrate. Thus, the linking between the piezoelectric substrate and the polymer layer of the donor substrate takes place via the dielectric layer, which makes it possible to obtain a stable bond in order for the donor substrate to subsequently be subjected to thermal and/or mechanical process stages without suffering degradation at the piezoelectric-polymer bond.

According to one embodiment, the polymer layer can be an adhesive layer polymerized in order to bond the piezoelectric substrate to the handling substrate via the intermediate layer of the piezoelectric substrate. The presence of a crosslinked polymer layer makes it possible to obtain a stable bond with the intermediate layer of the piezoelectric substrate.

According to one embodiment, the piezoelectric substrate can be a lithium tantalate (LTO), lithium niobate (LNO), aluminum nitride (AlN), lead zirconate titanate (PZT), langasite or langatate substrate. The donor substrate according to the present disclosure can comprise these materials, which play a major role in devices making use of the piezoelectric effect.

The object of the present disclosure can also be achieved by a process for transfer of a piezoelectric layer onto a support substrate, comprising the stages of providing a donor substrate as described above with a piezoelectric substrate that is thinned or obtained by the implementation of the manufacturing process as described above, forming a weakened zone inside the piezoelectric substrate, providing a support substrate, in particular, a silicon-based substrate, attaching the donor substrate to the support substrate, in order to obtain a donor substrate-support substrate assembly, and carrying out fracturing along the weakened zone in order to separate a piezoelectric layer from the remainder of the donor substrate.

In such a process, by virtue of the use of a donor substrate obtained according to the manufacturing process described earlier, which exhibits a better mechanical stability at the level of the linking of the piezoelectric material with the polymer layer by virtue of the presence of the intermediate layer, the risk of debonding of the piezoelectric material in the support substrate-donor substrate assembly during the implementation of the different process stages applied a posteriori to the donor substrate-support substrate assembly, and which is due to the differences in the thermal expansion coefficients is reduced. Thus, the use of donor substrates manufactured according to the present disclosure makes possible the manufacture of POI substrates with a better yield.

### BRIEF DESCRIPTION OF THE DRAWINGS

The invention and its advantages will be explained in more detail subsequently by means of preferred embodiments and with the support, in particular, of the following accompanying figures, in which the reference numbers identify characteristics of the invention.

FIG. 1A diagrammatically represents a process for the manufacture of a donor substrate and a donor substrate according to a first embodiment of the present disclosure.

FIG. 1B diagrammatically represents a process for the manufacture of a donor substrate and a donor substrate according to a first alternative form of the first embodiment of the present disclosure.

FIG. 2 diagrammatically represents a process for the manufacture of a donor substrate and a donor substrate according to a second alternative form of the first embodiment of the present disclosure.

FIG. 3 diagrammatically represents a process for the manufacture of a donor substrate and a donor substrate according to a second embodiment of the present disclosure.

FIG. 4 diagrammatically represents a process for the transfer of a piezoelectric layer according to a third embodiment of the present disclosure.

### DETAILED DESCRIPTION

The invention will be described in more detail using advantageous embodiments in an exemplary way and with reference to the drawings. The embodiments described are simply possible configurations and it should be kept in mind that the individual characteristics as described above can be provided independently of one another or can be omitted entirely during the implementation of the present disclosure.

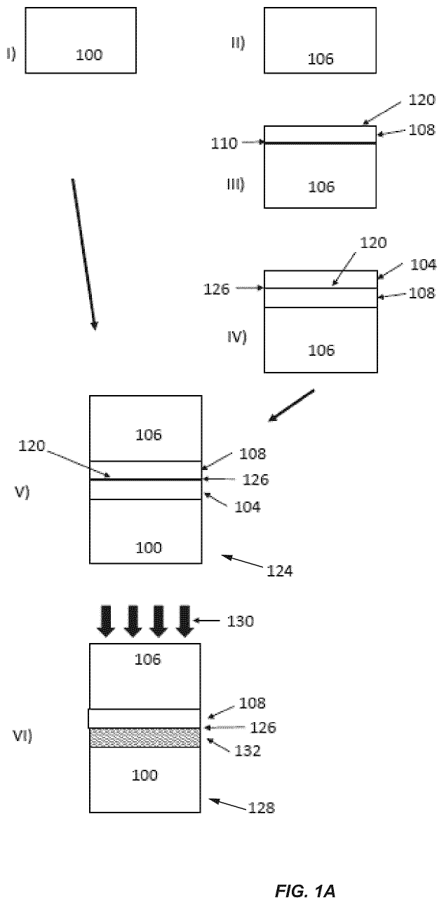

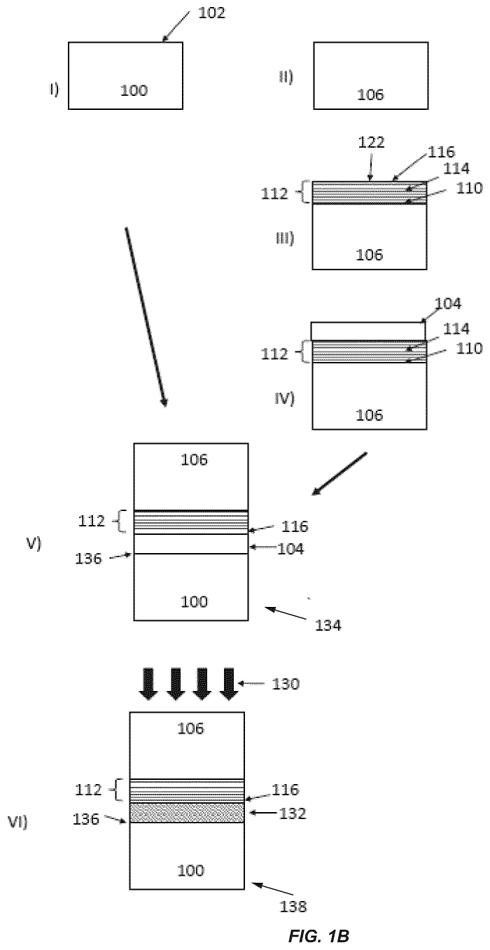

FIG. 1A diagrammatically illustrates a process for the manufacture of a donor substrate used for the transfer of a piezoelectric layer of the donor substrate onto a support substrate according to a first embodiment of the present disclosure.

The process for the manufacture of a donor substrate begins with stage I) of providing a handling substrate 100, in particular, a bulk substrate. A bulk substrate is a substrate based on just one material typically with a thickness of between 300 μm and 800 μm, in particular, between 350 μm and 800 μm. The handling substrate 100 is made of a material the thermal expansion coefficient of which is close to that of the material of the support substrate onto which the piezoelectric layer is intended to be transferred. The term “close” is understood to mean a difference in thermal expansion coefficient between the material of the handling substrate 100 and the material of the support substrate of less than or equal to 5% and preferably equal to or in the vicinity of 0%.

The handling substrate 100 can be a substrate based on silicon, on sapphire, on aluminum nitride (AlN), on silicon carbide (SiC) or else on gallium arsenide (GaAs). The handling substrate 100 can be a crystalline or polycrystalline substrate.

During stage II), a piezoelectric substrate 106 is provided. It is preferably a bulk substrate formed of just one piezoelectric material, the thickness of which is typically of the order of at least 300 μm, preferably of at least 350 μm. According to an alternative form, the substrate of piezoelectric material 106 can also be a thick layer of piezoelectric material between 25 μm and 50 μm, formed on another substrate.

The piezoelectric material can, for example, be lithium tantalate (LTO), lithium niobate (LNO), aluminum nitride (AlN), lead zirconate titanate (PZT), langasite or langatate.

According to the present disclosure, a stage III) of formation of an intermediate layer 108 on a free surface 110 of the piezoelectric substrate 106 is carried out. The formation of the intermediate layer 108 on the free surface 110 the piezoelectric substrate can be carried out by deposition by spin coating or by a thermal growth technique, or plasma-enhanced deposition such as PECVD or PVD.

Before carrying out the formation of the intermediate layer 108, one or more stages of cleaning, brushing or polishing the surface of the piezoelectric substrate 106 can be carried out in order to remove the presence of particles and dust in order to thus obtain a cleaner free surface 110, which makes it possible to obtain an intermediate layer 108 of better quality.

According to the present disclosure, the intermediate layer 108 formed on the piezoelectric substrate 106 is a dielectric layer, for example, a layer based on silicon oxide, or based on silicon nitride Si₃N₄, or else a layer comprising a combination of silicon nitride and oxide SiOₓN_{y}.

According to an alternative form of the invention, a stage of activation of the surface of the intermediate layer 108 formed on the piezoelectric substrate 106 can be carried out in order to activate the free surface 122 of the intermediate layer 108. In particular, this activation treatment can be a plasma treatment, more particularly still an oxygen-based plasma treatment.

A plasma treatment is a treatment by the dry route, which makes possible the functionalization, the activation or the cleaning of the surface, or a combination of these effects, by oxidation. The oxidation of the surface molecules makes it possible to increase the surface tension of a support creating pendant bonds on the surface. The plasma treatment makes possible the creation of free radicals at the surface, which promotes the successive adhesion of a thin layer in contact with these free radicals. Thus, the plasma surface treatment makes it possible to improve the chemical characteristics of the surface 122 of the dielectric layer 108 of the piezoelectric substrate 106 by creating pendant bonding sites for better adhesion to a layer that is formed or brought into contact with the surface 122 of the layer 108 of the piezoelectric substrate 106 during the continuation of the process.

According to the present disclosure, a stage IV) of deposition of a polymer layer 104 on the intermediate layer 108 of the piezoelectric substrate 106 is carried out. The polymer layer 104 is thus in direct contact with the intermediate layer 108 of the piezoelectric substrate 106 at the interface 126. The presence of the intermediate layer 108 between the piezoelectric substrate 106 and the polymer layer 104 results in better adhesion with the polymer layer 104 and thus with the piezoelectric substrate 106, compared with direct linking between the polymer layer 104 and the piezoelectric substrate 106 of the state of the art. This is because it is possible to choose an intermediate layer 108 that exhibits good adhesion to the piezoelectric substrate 106 and also to the polymer layer 104.

The deposition of the polymer layer 104 is advantageously carried out by spin coating. This technique consists in spinning the substrate on which the deposition of the polymer layer 104 is intended to take place on itself at a given speed, in order to spread the polymer layer 104 uniformly over the entire surface of the piezoelectric substrate 106 by centrifugal force. To this end, the piezoelectric substrate 106 is typically placed and held by applying vacuum on a rotary plate. The thickness of the polymer layer 104 obtained depends on the parameters used during the deposition of the layer, which is to say, for example, on the speed and duration of rotation of the substrate and on the volume of the polymer solution deposited on the surface of the piezoelectric substrate 106. The thickness of the polymer layer 104 is typically of between 1 μm and 6 μm, preferably 3.5 μm.

The polymer layer 104 can be a photopolymerizable layer, in particular, based on thiol-ene resin. For example, the layer sold under the reference “NOA 61” by Norland Products can be used in the present disclosure as polymer layer 104.

After the deposition by spin coating of the polymer layer 104 on the piezoelectric substrate 106, a heat treatment can be carried out to improve the adhesion of the polymer layer 104 to the activated surface 122 of the intermediate layer 108 of the piezoelectric substrate 106.

In the alternative form in which a stage of activation of the surface 122 of the intermediate layer 108 is carried out, the stage of deposition of the polymer layer 104 is carried out after the stage of activation of the surface 122 of the intermediate layer 108. Thus, the deposition of the polymer layer 104 is carried out on the activated surface 122 of the intermediate layer 108, in direct contact with the activated surface 122.

According to the present disclosure, the piezoelectric substrate 106 obtained after stage IV) is subsequently assembled with the handling substrate 100 obtained in stage I) during an assembling stage V) in order to form the donor substrate 124.

The assembling of the piezoelectric substrate 106 on the handling substrate 100 is carried out such that the polymer layer 104 is positioned in contact with the layer 108 of the piezoelectric substrate 106 and the handling substrate 100.

Once the two substrates are assembled, a bonding stage VI) is carried out in order to bond the piezoelectric substrate 106 to the handling substrate 100 in order to form a stable donor substrate 128.

The polymer layer 104 is subjected to a crosslinking treatment in order to modify the mechanical properties of the polymer layer 104. Crosslinking is the general term denoting the process of formation of covalent bonds or of relatively short sequences of chemical bonds in order to join two polymer chains. When the polymer chains are crosslinked, the polymer layer 104 becomes stiffer. Covalent chemical crosslinkings are stable mechanically and thermally, so that, once formed, they are difficult to break.

A crosslinking treatment can be carried out by use of heat, of pressure, by a change in pH or by irradiation. According to the present disclosure, the crosslinking treatment can be carried out by irradiation by a light flux 130 of the polymer layer 104. The irradiation 130 is carried out through the piezoelectric substrate 106 or the handling substrate 100 in order to crosslink the polymer layer 104 and to obtain a crosslinked polymer layer 132, also called polymerized layer 132.

The irradiation 130 can be carried out using a light source, preferably a laser. The light radiation 130, or light flux, is preferably ultraviolet (UV) radiation, preferably with a wavelength of between 320 nm and 365 nm.

The thickness of the crosslinked polymer layer 132 is preferably of between 1 μm and 6 μm, in particular, approximately 3.5 μm. This thickness depends, in particular, on the material of the polymer layer 104 deposited before bonding, on the thickness of the polymer layer 104 and on the irradiation conditions.

The crosslinking of the polymer layer 104 by UV irradiation 130 makes it possible to release radicals that will trigger the polymerization of the polymer layer 104. The polymerization of the polymer layer 104 results in chemical bonds that are mechanically and thermally stable, so that, once formed, they are difficult to break. The linking between the polymerized layer 132 and the intermediate dielectric layer 108 thus ensures the mechanical cohesion of the donor substrate 128 by keeping the handling substrate 100 and the piezoelectric substrate 106, which form the donor substrate 128, bonded together.

In the alternative form in which a surface activation treatment is carried out at the surface 122 of the intermediate layer 108, the adhesion between the crosslinked polymer layer 132 and the dielectric layer 108 of the piezoelectric substrate 106 at the interface 126 is improved due to the activated surface of the intermediate layer 108. This is because the pendant bonds present on the activated surface of the intermediate dielectric layer 108 of the piezoelectric substrate 106 will form covalent bonds with the pendant bonds present at the surface of the polymer layer 104. Thus, the contact interface 126 between the intermediate layer 108 of the piezoelectric substrate 106 and the polymer layer 104 is consolidated/reinforced by virtue of the surface activation treatment of the intermediate layer 108 and results in an improved mechanical stability of the donor substrate 124 with respect to the state of the art.

In a first alternative form of the first embodiment, illustrated in FIG. 1B, stage III) of the process of formation of an intermediate layer 108 is replaced by the formation of a plurality 112 of sublayers 114, each sublayer 114 of the plurality 112 of sublayers 114 being the same or being different because of their material or because of their properties or else because of their thicknesses. All the other stages I) to II) and IV) to VI) are the same as those described for FIG. 1A. Thus, for a detailed description of these stages, reference is made to the description of FIG. 1A.

At least one layer 116 of the sublayers 114 of the plurality 112 of sublayers is a dielectric layer 116, in particular, a layer based on silicon oxide, or on silicon nitride Si₃N₄ or a combination of silicon nitride and oxide SiOₓN_{y}. In particular, the upper layer 116, which corresponds to the final layer of the plurality 112 of sublayers 114 starting from the piezoelectric substrate 106, is a layer based on silicon oxide, or on silicon nitride Si₃N₄ or a combination of silicon nitride and oxide SiOₓN_{y}. The plurality 112 of sublayers 114 can be a superposition of silicon oxide layer and of silicon nitride Si₃N₄ layer.

In this alternative form, the deposition of the polymer layer 104 takes place on the upper layer 116 of the plurality 112 of sublayers 114. Thus, the upper layer 116 is sandwiched between the polymer layer 104 and the remainder of the sublayers 114 of the plurality 112 of sublayers 114 of the piezoelectric substrate 106.

In this alternative form, the assembling of the piezoelectric substrate 106 on the handling substrate 100 is carried out at the interface 136 between the free surface 102 of the handling substrate 100 and the polymer layer 104 formed on the upper layer 116 of the piezoelectric substrate 106. Thus, the upper layer 116 is sandwiched between the polymer layer 104 on the handling substrate and the remainder of the sublayers 114 of the plurality 112 of sublayers 114 of the piezoelectric substrate 106 to form the heterostructure 134 that becomes, after stage VI), the donor substrate 138.

According to an alternative form, a surface activation treatment can be carried out as in the process described with respect to FIG. 1A. The plasma treatment is carried out on the free surface 122 of the upper layer 116 of the plurality 112 of sublayers 114.

The use of a dielectric layer 108, 116 formed on a piezoelectric substrate 106 subsequently makes it possible to assemble the piezoelectric substrate 106 with another handling substrate 100 via a polymer layer 104 deposited on this dielectric layer 108, 116 in a way that is sturdy and stable to form a donor substrate. The mechanical stability of the donor substrate 128, 138 thus obtained by virtue of the dielectric layer-polymer layer bond makes it possible for this donor substrate 128, 138 to be subsequently used in other processes and to be subjected to different thermal and mechanical process stages without undergoing deformation at the interface of the piezoelectric substrate 106.

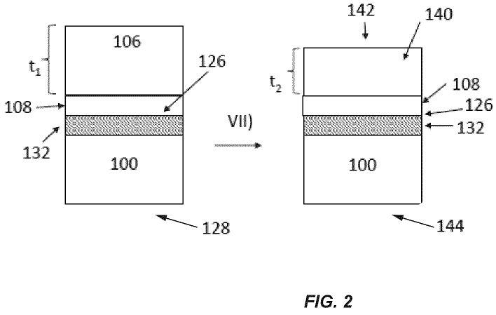

FIG. 2 diagrammatically represents a process for the manufacture of a donor substrate for the transfer of a piezoelectric layer onto a support substrate according to an alternative form of the first embodiment of the present disclosure.

None of the characteristics in common with the first embodiment using the same reference number as above will be described again but reference is made to their detailed description above.

The process illustrated in FIG. 2 comprises, after stage VI) illustrated in FIG. 1A, a stage of thinning VII) the piezoelectric substrate 106 of the donor substrate 128 obtained according to the process of the first embodiment and its first alternative form. In the same way, the donor substrate 138 can be used.

The thinning stage VII) can be carried out by a process of grinding or else by a process of chemical etching of the piezoelectric substrate 106 in order to reduce the thickness t₁ of the substrate of piezoelectric substrate 106 of the donor substrate 128 in order to obtain either a thinned piezoelectric substrate 140 with a thickness/of less than t₁, or a piezoelectric layer 140 with a thickness t₂ of the order of 20 μm, or else between 5 μm and 25 μm. A treatment of the free surface 142 of the piezoelectric layer 140 obtained can be carried out once the thinning stage VII) is complete in order to improve the quality of the free surface 142 of the piezoelectric layer 140.

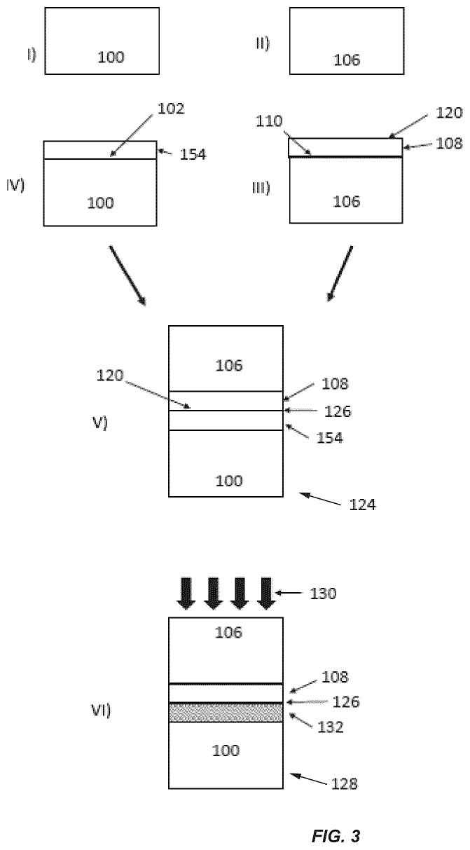

FIG. 3 illustrates the second embodiment of the present disclosure, in which the stage of deposition of the polymer layer 154 is carried out on the handling substrate 100, instead of being carried out on the piezoelectric substrate 106. All the other stages I), II), III) and V) to VII) are the same as in the first embodiment and its alternative forms. None of the characteristics in common with the first embodiment and its alternative forms and using the same reference number as above will be described again but reference is made to their detailed description above.

During stage IV) of deposition of the polymer layer 154, the polymer layer 154 is deposited directly in contact with the free surface 102 of the handling substrate 100. The handling substrate 100 can first be subjected to one or more stages of cleaning, brushing or polishing its free surface 102 in order to reduce the presence of particles or dust before carrying out the deposition of the polymer layer 154.

During the assembling stage V), the polymer layer 154 of the handling substrate 100 is brought into direct contact with the intermediate layer 108 of the piezoelectric substrate 106. Thus, the contact interface 126 between the polymer layer 154 and the intermediate layer 108 of the piezoelectric substrate 106 also exhibits better adhesion. This is because, in the same way as described above, it is possible to choose an intermediate layer 108 that exhibits good adhesion to the piezoelectric substrate 106 and also to the polymer layer 154. Thus, the contact interface 126 between the piezoelectric substrate 106 and the polymer layer 154 via the intermediate layer 108 is consolidated/reinforced and results in an improved mechanical stability of the donor substrate 124 with respect to the state of the art.

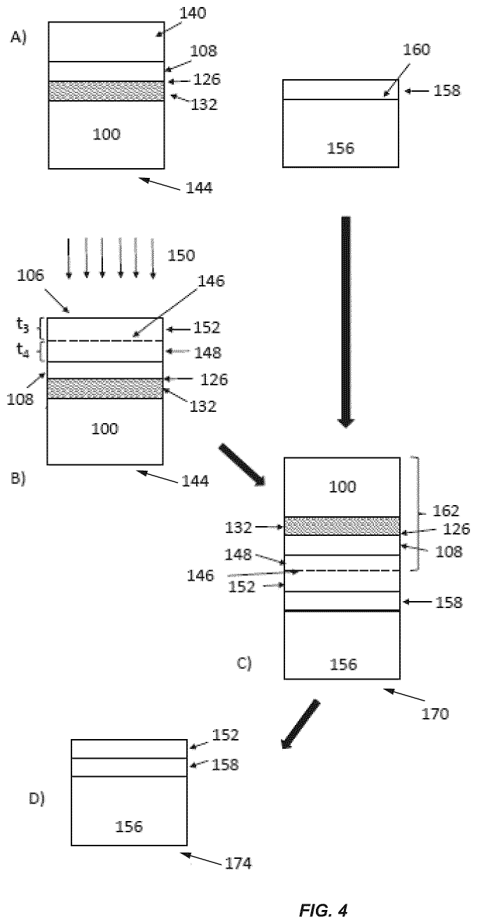

FIG. 4 diagrammatically represents a process for the transfer of a piezoelectric layer according to a second embodiment of the present disclosure using the donor substrate 144. According to alternative forms, the process can be carried out with the donor substrate 128, 138 obtained according to the other alternative forms described with respect to FIG. 1A, 1B, or 2.

During stage A), the donor substrate 144 and a support substrate 156 are provided. The support substrate 156 can be a bulk substrate based on silicon, on sapphire, on aluminum nitride (AlN), on silicon carbide (SiC) or else on gallium arsenide (GaAs). The support substrate 156 can be a crystalline or polycrystalline substrate. The donor substrate 144 shows a mechanical stability that allows it to be used in the process for transfer of the piezoelectric layer 152 onto the support substrate 156.

As illustrated in FIG. 4, the support substrate 156 can comprise a dielectric layer 158 previously formed on the free surface 160 of the support substrate 156, for example, by deposition by spin coating or by a deposition technique, such as plasma deposition or evaporation deposition, or thermal growth. The dielectric layer 158 is, for example, a layer of silicon oxide, a layer of silicon nitride Si₃N₄ or a layer comprising a combination of silicon nitride and oxide, also known as silicon oxynitride, SiOₓN_{y}, or a superposition of a layer of oxide and of a layer of nitride. According to an alternative form, the formation of the dielectric layer 158 can be followed by a heat treatment in order to improve the adhesion of the dielectric layer 158 to the support substrate 156. A surface treatment in order to improve the quality of the surface of the dielectric layer 158 formed can also be carried out.

The dielectric layer 158 can also be a layer of natural oxide that is formed on the free surface 160 of the support substrate 156.

In an alternative form, other layers can be present on the support substrate 156 and/or the dielectric layer 158, for example, layers for producing a Bragg mirror or a trapping layer. In yet another alternative form, the support substrate 156 is provided without a dielectric layer 158 and/or without a layer of natural oxide.

In an alternative form, a dielectric layer can be provided on the piezoelectric layer 140 of the donor substrate 144 instead of or in addition to the dielectric layer 158 formed on the support substrate 156.

In an alternative form, the support substrate 156 can also comprise other layers. For example, layers for producing a Bragg mirror or a trapping layer can be present on the support substrate 156. In particular, a trapping layer of polycrystalline, amorphous or porous silicon type can be present, with a thickness varying between 500 nm and 5 μm.

A stage B) of forming a weakened zone 146 in the piezoelectric layer 140 of the donor substrate 144 is carried out so as to delimit the piezoelectric layer 152 to be transferred from the remainder 162 of the piezoelectric layer 140.

This stage of formation of a weakened zone 146 is carried out by an implantation 150 of atomic or ionic entities in the piezoelectric layer 140 of the donor substrate 144. The atomic or ionic implantation 150 is carried out in such a way that the weakened zone 146 is located inside the piezoelectric layer 140 and separates a piezoelectric layer 152 from the remainder 162 of the piezoelectric layer 140. The atomic or ionic entities are implanted at a predetermined depth of the piezoelectric layer 140, which determines the thickness t₃ of the piezoelectric layer 152 to be transferred and the thickness t₄ of the remainder 148 of the piezoelectric layer 140. The thickness t₃ is typically between 50 nm and 1 μm, in particular, of the order of 600 nm. Non-limitingly, a dielectric layer can be formed on the piezoelectric layer 140 obtained of the donor substrate 144. This dielectric layer is, for example, a layer of silicon oxide, a layer of silicon nitride Si₃N₄ or else a layer comprising a combination of silicon nitride and oxide, also known as silicon oxynitride, SiOₓN_{y}, or a superposition of a layer of oxide and of a layer of nitride. According to an alternative form, the formation of this dielectric layer can be followed by a heat treatment in order to improve the adhesion of the dielectric layer to the piezoelectric layer 140. A surface treatment for improving the quality of the surface of this dielectric layer formed can also be carried out, in particular, after the stage of implantation 150 and before stage C) mentioned below.

During stage C) of the process of transfer according to the present disclosure, the donor substrate 144 is assembled with the support substrate 156 in order to obtain a support substrate-donor substrate assembly 170. The assembly 170 of the donor substrate 144 with the support substrate 156 takes place at the level of the dielectric layer 158, in such a way that the piezoelectric layer 140 of the donor substrate 144 is in direct contact with the dielectric layer 158 and the piezoelectric layer 152 to be transferred is sandwiched between the support substrate 156 and the remainder 162 of the donor substrate 144. In an alternative form, the assembly 170 of the donor substrate 144 with the support substrate 156 takes place between the dielectric layer 158 and a dielectric layer formed on the donor substrate 144, as mentioned above.

The assembling takes place by molecular adhesion between the two substrates, at the piezoelectric-support substrate interface, in a known way.

Subsequently, a stage D) of fracturing along the weakened zone 146 of the donor substrate 144 is carried out by contributing thermal and/or mechanical energy in order to separate the piezoelectric layer 152 from the remainder 162 of the donor substrate 144.

Thus, the POI substrate 174 comprising the support substrate 156, the dielectric layer 158 and the transferred piezoelectric layer 152 is obtained.

By virtue of the presence of the intermediate dielectric layer 108 between the piezoelectric layer 140 and the polymer layer 120, 132, it becomes possible to reduce the risk of a debonding between the piezoelectric layer 140 and the polymer layer 120, 132 of the donor substrate 144 during the fracturing of the donor substrate 144. Thus, the use of the donor substrate 144 manufactured according to the present disclosure makes possible the manufacture of a POI substrate 174 with a better yield.

The embodiments described are simply possible configurations and it should be kept in mind that the individual characteristics of the different embodiments can be combined with one another or provided independently of one another.

1.-11. (canceled)

12. A method of manufacturing a donor substrate for the transfer of a piezoelectric layer onto a support substrate, comprising:
providing a handling substrate;
providing a piezoelectric substrate;
forming an intermediate layer on a free surface of the piezoelectric substrate;
depositing a polymer layer on the intermediate layer of the piezoelectric substrate or on the handling substrate; and
assembling the piezoelectric substrate on the handling substrate to form the donor substrate.

13. The method of claim 12, wherein depositing the polymer layer on the intermediate layer of the piezoelectric substrate or on the handling substrate comprises depositing the polymer layer on the intermediate layer of the piezoelectric substrate.

14. The method of claim 12, wherein depositing the polymer layer on the intermediate layer of the piezoelectric substrate or on the handling substrate comprises depositing the polymer layer on the handling substrate.

15. The method of claim 12, wherein forming the intermediate layer on the piezoelectric substrate comprises forming a dielectric layer.

16. The method of claim 15, wherein forming the dielectric layer comprises forming the dielectric layer to comprise silicon oxide, silicon nitride, or silicon oxynitride.

17. The method of claim 12, further comprising performing a surface treatment on the intermediate layer.

18. The method of claim 17, wherein performing the surface treatment on the intermediate layer comprises performing a plasma treatment on the intermediate layer.

19. The method of claim 18, wherein performing the plasma treatment on the intermediate layer comprises performing an oxygen plasma treatment on the intermediate layer.

20. The method of claim 12, further comprising thinning the piezoelectric substrate of the donor substrate.

21. The method of claim 20, wherein thinning the piezoelectric substrate comprises grinding the piezoelectric substrate.

22. The method of claim 12, further comprising selecting the handling substrate to be a silicon-based substrate.

23. A donor substrate for the transfer of a piezoelectric layer, comprising:
a handling substrate;
a piezoelectric substrate;
a polymer layer between the handling substrate and the piezoelectric substrate; and
an intermediate layer between the piezoelectric substrate and the polymer layer.

24. The donor substrate of claim 23, wherein the handling substrate comprises a silicon-based substrate.

25. The donor substrate of claim 23, wherein the intermediate layer comprises a plurality of sublayers.

26. The donor substrate of claim 23, wherein the intermediate layer comprises at least one dielectric layer.

27. The donor substrate of claim 26, wherein the at least one dielectric layer comprises silicon oxide, silicon nitride, or silicon oxynitride.

28. The donor substrate of claim 23, wherein the intermediate layer is in direct contact with the polymer layer.

29. The donor substrate of claim 23, wherein the piezoelectric substrate is a lithium tantalate substrate, a lithium niobate substrate, an aluminum nitride substrate, a lead zirconate titanate substrate, a langasite substrate, or a langatate substrate.

30. A method of transferring a piezoelectric layer onto a support substrate, comprising:
providing a donor substrate according to claim 23;
forming a weakened zone within the piezoelectric substrate of the donor substrate;
providing a support substrate;
attaching the donor substrate to the support substrate to obtain a support substrate-donor substrate assembly; and
fracturing along the weakened zone to separate a piezoelectric layer from a remainder of the donor substrate.

31. The method of claim 30, further comprising selecting the support substrate to comprise a silicon-based substrate.
